(19) United States
(12) Patent Application Publication
(10) Pub. No.: US 2025/0370940 A1
(43) Pub. Date: Dec. 4, 2025

(54) HOST DEVICE AND DRIVING METHOD

(71) Applicant: MediaTek Singapore Pte. Ltd., Singapore (SG)

(72) Inventor: Zhihao ZENG, Shenzhen (CN)

(21) Appl. No.: 18/767,241

(22) Filed: Jul. 9, 2024

(30) Foreign Application Priority Data
May 30, 2024 (CN) 202410692255.2

(51) Int. Cl. G06F 13/20; G06F 13/38; G06F 13/42; H03M 1/12

(52) U.S. Cl. CPC G06F 13/20; G06F 13/382; G06F 13/4282; G06F 2213/0042; H03M 1/12

(57) ABSTRACT

A host device is provided and coupled to an electronic device. The host device includes an I/O port, a controller, and an ADC. The I/O port includes first and second VO pins. The first and second I/O pins are coupled to the electronic device. The controller is configured to drive the electronic device using a configuration parameter set. The ADC is coupled to the first I/O pin and the second I/O pin and configured to sample a first data signal on the first I/O pin to obtain a first voltage value and further to sample a second data signal on the second I/O pin to obtain a second voltage value. The controller receives the first voltage value and the second voltage value and changes the configuration parameter set according to the first voltage value and the second voltage value.

### CROSS REFERENCE TO RELATED APPLICATIONS

This Application claims priority of China Patent Application No. 202410692255.2, filed on May 30, 2024, the entirety of which is incorporated by reference herein.

### BACKGROUND OF THE INVENTION

### Field of the Invention

The invention relates to a host device, and more particularly to a driving method for a host device to drive an USB device.

### Description of the Related Art

USB On-The-Go (OTG) is a specification that allows USB devices, such as tablets or smartphones, to act as a host, allowing other USB devices, such as USB flash drives, digital cameras or keyboards, to be attached to them. Generally, a host uses a fixed parameter set to drive majority of USB OTG devices. However, when a USB device which has worse compatibility or is connected with a line not meeting a specific standard is attached to the host, the host may not drive the USB device using the fixed parameter set. Thus, how a host can select and use parameter sets adaptability to drive USB OTG devices is an important issue.

### BRIEF SUMMARY OF THE INVENTION

An exemplary embodiment of a host device is provided. The host device is coupled to an electronic device and comprises an input/output (I/O) port, a controller, and an analog-to-digital converter. The I/O port comprises a first I/O pin and a second I/O pin. The first I/O pin and the second I/O pin are coupled to the electronic device. The controller is coupled to the first I/O pin and the second I/O pin and configured to drive the electronic device using a configuration parameter set. The analog-to-digital converter is coupled to the first I/O pin and the second I/O pin and configured to sample a first data signal on the first I/O pin to obtain a first voltage value and further to sample a second data signal on the second I/O pin to obtain a second voltage value. The controller receives the first voltage value and the second voltage value and changes the configuration parameter set according to the first voltage value and the second voltage value.

An exemplary embodiment of a driving method for an electronic device is provided. The driving method comprises steps of inserting an electronic device to a host device, wherein an input/output (I/O) port of the host device comprises a first I/O pin and a second I/O pin which are coupled to the electronic device; driving the electronic device using a configuration parameter set; sampling a first data signal on the first I/O pin to obtain a first voltage value and a second data signal on the second I/O pin to obtain a second voltage value; and changing the configuration parameter set according to the first voltage value and the second voltage value.

According to the above embodiments, the host device can adaptability use different predetermined parameter sets for driving different electronic devices without being affected by the materials or quality of transmission lines.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows an exemplary embodiment of an electronic system;

FIG. 2A is a schematic diagram showing an exemplary predetermined parameter sets and corresponding predetermined voltage values according to an exemplary embodiment;

FIG. 2B is a schematic diagram showing an exemplary predetermined parameter sets and a difference voltage values according to an exemplary embodiment; and

FIG. 3 shows an exemplary embodiment of a driving method.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

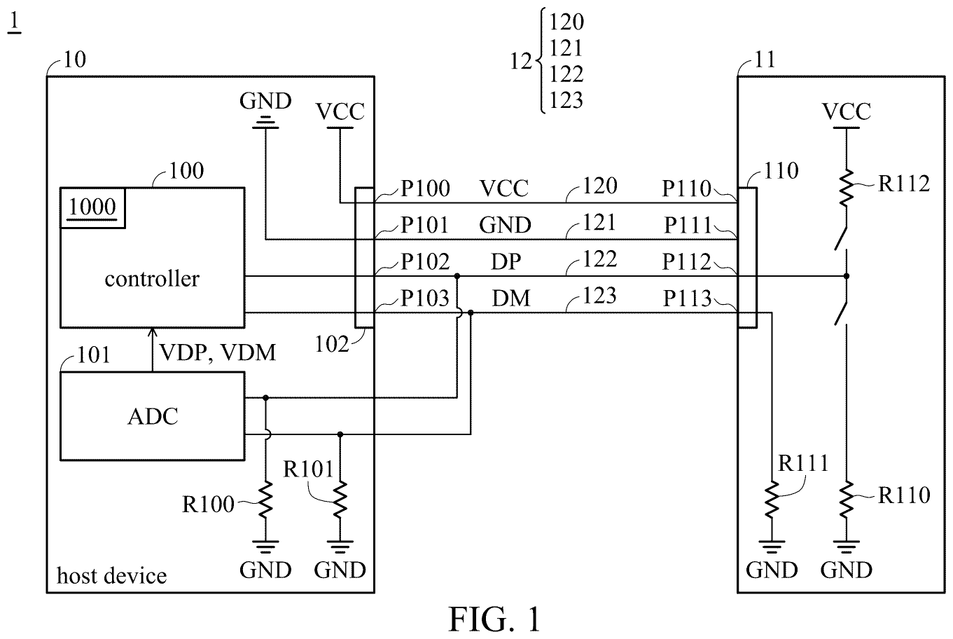

FIG. 1 shows an exemplary embodiment of an electronic system. As shown in FIG. 1, an electronic system 1 comprises a host device 10 and an electronic device 11. In an embodiment, the electronic device 11 is a high-speed device, for example, a USB OTG (On-The-Go) high-speed device, for example, and the host device 10 is a device that is capable of supporting a high-speed device, for example, a mobile phone, a tablet, a laptop, or a desktop computer.

The host device 10 comprises a controller 100, an analog-to-digital converter (ADC) 101, and an input/output (I/O) port 102. The host device 10 is coupled to the electronic device 11 through a transmission cable 12. Referring to FIG. 1, the I/O port 102 comprises four I/O pins P100-P103, and the transmission cable 12 comprises four lines 120-123 which are connected to the I/O pins P100-P103 respectively. The electronic device 11 comprises an I/O port 110 which comprises four I/O pins P110-P113. The I/O pins P100-P103 of the I/O port 102 are coupled to the I/O pins P110-P113 of the I/O port 110 through the lines 120-123, respectively. The controller 100 are coupled to the I/O pins P102-P103 of the I/O port 102. In the embodiment, the host device 10 provides an operating voltage VCC to the electronic device 11 through the I/O pin P100, the line 120, and the I/O pin P110. The host device 10 is coupled to the electronic device 11 through the I/O pin P101, the line 121, and the I/O pin P111 and further to a ground GND. A data signal transmitted between the I/O pin P102 and the I/O pin P112 on the line 122 and a data signal transmitted between the I/O pin P103 and the I/O pin P113 on the line 123 form a differential pair of signals. In the embodiment, the I/O pins P100-P103 are referred to as a VCC pin P100, a GND pin P101, a DP pin P102, and DM pin P103, the I/O pins P110-P113 are referred to as a VCC pin P110, a GND pin P111, a DP pin P112, and a DM pin P113, and the line 120-123 are as a VCC line 120, a GND line 121, a DP line 122, and a DM line 123.

The host device 10 further comprises a terminal resistor R100 is connected to the DP pin P102 and a terminal resistor R101 is connected to the DM pin P103. The electronic device 11 further comprises a terminal resistor R110 which is connected to the DP pin P112 and a terminal resistor R111 which is connected to the DM pin P113. For example, each of the terminal resistor R100-R101 and R110-R111 is 45 ohm.

The ADC 101 is coupled to the DP pin P102 and the DM pin P103. In the embodiment, the ADC 101 samples a positive data signal DP on the DP pin P102 to obtain a voltage value VDP and further samples a minus data signal DM on the DM pin P103 to obtain a voltage value VDM. That is, the ADC 101 samples the data signal on the portion of the DP line 122 close to the host device 10 and further samples the data signal on the portion of the DM line 123 close to the host device 10, thereby obtaining the voltage values VDP and VDM respectively. The ADC 101 is coupled to the controller 100. The ADC 101 transmits the voltage values VDP and VDM to the controller 100.

The controller 100 comprises a memory 1000. The memory 1000 stores a plurality of predetermined parameter sets that are determined previously for driving USB devices. The controller 100 defines a plurality of predetermined voltage values for the plurality of predetermined parameter sets. Moreover, for each of the plurality of predetermined voltage values, the controller 100 defines one predetermined voltage range for a determination operation performed by the controller 100. Thus, the plurality of determined parameter sets correspond to the plurality of predetermined voltage ranges respectively. In the embodiment, eight predetermined parameter sets, which correspond to eight predetermined voltage values and further to eight predetermined voltage ranges respectively, are provided by the controller 100.

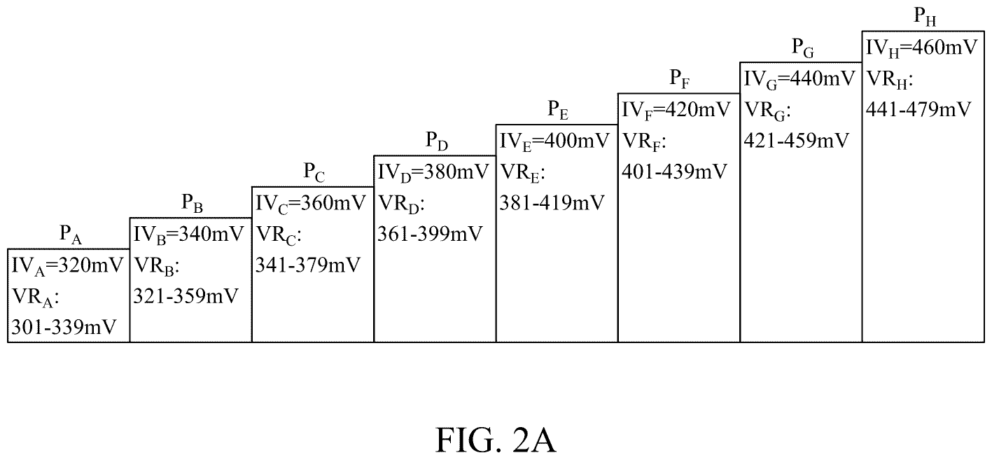

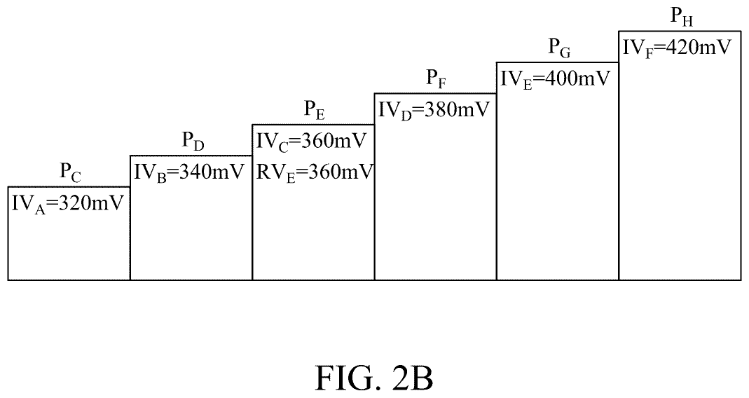

In an embodiment, the controller 100 defines the plurality of predetermined voltage values in a predetermined sequence. Referring to FIG. 2A, the controller 100 provides the eight predetermined parameter sets P_{A}-P_{H}. In the predetermined sequence, the controller 100 defines the eight predetermined voltage values IV_{A}-IV_{H} from the minimum to the maximum. For example, the predetermined voltage values IV_{A}-IV_{H} are defined as 320 mV, 340 mV, 360 mV, 380 mV, 400 mV, 420 mV, 440 mV, and 460 mV respectively, wherein there is a voltage interval of 20 mV between any two adjacent predetermined voltage values.

For the predetermined voltage value IV_{A} of 320 mV, the controller 100 defines the predetermined voltage range VR_{A} as 301 mV-339 mV; for the predetermined voltage value IV_{B} of 340 mV, the controller 100 defines the predetermined voltage range VR_{B} as 321 mV-359 mV; for the predetermined voltage value IV_{C} of 360 mV, the controller 100 defines the predetermined voltage range VR_{C} as 341 mV-379 mV; for the predetermined voltage value IV_{D} of 380 mV, the controller 100 defines the predetermined voltage range VR_{D} as 361 mV-399 mV; for the predetermined voltage value IVE of 400 mV, the controller 100 defines the predetermined voltage range VRE as 381 mV-419 mV; for the predetermined voltage value IV_{F} of 420 mV, the controller 100 defines the predetermined voltage range VR_{F} as 401 mV-439 mV; for the predetermined voltage value IV_{G} of 440 mV, the controller 100 defines the predetermined voltage range VG_{G} as 421 mV-459 mV; for the predetermined voltage value IV_{H} of 460 mV, the controller 100 defines the predetermined voltage range VG_{H} as 441 mV-479 mV.

As described above, the electronic device 11 is a high-speed device, and, thus, a pull-up resistor R112 is provided for recognition. When the electronic device 11, in which the pull-up resistor R112 is connected to the DP pin P112 and the terminal resistor R111 is disconnected from the DP pin P112, is attached to the host device 10 through the I/O port 110, the transmission cable 12, and the I/O port 102, the host device 10 determines that the electronic device 11 is a high-speed device according to the high voltage level of the signal on the DP line 112 induced by the pull-up resistor R112. The host device 10 first uses one of the predetermined parameter sets PA-PH as a default configuration parameter set and then operates in a handshake stage according to the default configuration parameter set to drive the electronic device 11 by communicating with the electronic device 11. In the handshake stage, the controller 100 sends a Set_Port_Feature request to reset the electronic device 11. For the reset operation, the voltage levels of the signals on the DP line 122 and the DM line 123 are low (for example, 0V) for at least 10 ms, that is, the voltage levels of the signals on the DP line 122 and the DM line 123 are at the state SEO ((DP, DM)=(0V, 0V)) for 10 ms.

After the electronic device 11 is reset, the electronic device 11 sinks a current of 17.78 mA to the DM pin P113 through an internal current source. The voltage level of the signal on the DM line 123 is switched to 800 mV. The voltage level of the signal on the DP line 112 and the voltage level of the signal on the DM line 113 form a Chirk P signal ((DP, DM)=(0V, 800 mV)). When the host device 10 detects the Chirk P signal, the host device 10 replies three pairs of K, J signals and ends the reset operation.

When the electronic device 11 detects these three pairs of K, J signals, the electronic device 11 is switched to a high-speed mode within 500 us. Then, the pull-up resistor R112 is disconnected from the DP pin P112, and the terminal resistor R110 is connected to the DP pin P112. At this time, the amplitude of the voltage levels of the signals on the DP line 112 and the DM line 113 is switched to 400 mV, in other words, the absolute value of the difference between the voltage levels of the signals on the DP line 112 and the DM line 113 are 400 mV.

Ideally, in the high-speed mode, after the terminal resistor R110 is connected to the DP pin P112, the amplitude of the voltage levels of the signals on the DP pin P102 and the DM pin P103 and the amplitude of the voltage levels of the signals on the DP pin P112 and the DM pin P113 are equal to the amplitude (400 mV) of the voltage levels of the signals on the DP line 112 and the DM line 113. However, in practice, due to the material or quality of the transmission cable 12, there may be an impedance on the transmission cable 12, which induces difference between the amplitude of the voltage levels of the signals on the DP pin P102 and the DM pin P103 and the amplitude of the voltage levels of the signals on the DP pin P112 and the DM pin P113.

According to the embodiment of the present invention, after the terminal resistor R110 is connected to the DP pin P112, the host device 10 determines whether the currently used parameter sets is appropriate. When the host device 10 determines that the currently used parameter sets is not appropriate, the host device 100 uses another parameter set from the plurality of determined parameter sets according to the voltage level of the signal (the positive data signal DP) on the DP pin P102 and the voltage level of the signal (the minus data signal DM) on the DM pin P103, thereby increasing the rate at which the host device 10 drives the electronic device 11 successfully without being affected by the material or quality of transmission line 120.

The detailed operation of the host device 10 will be described with FIG. 1 to FIG. 3 in the following paragraphs.

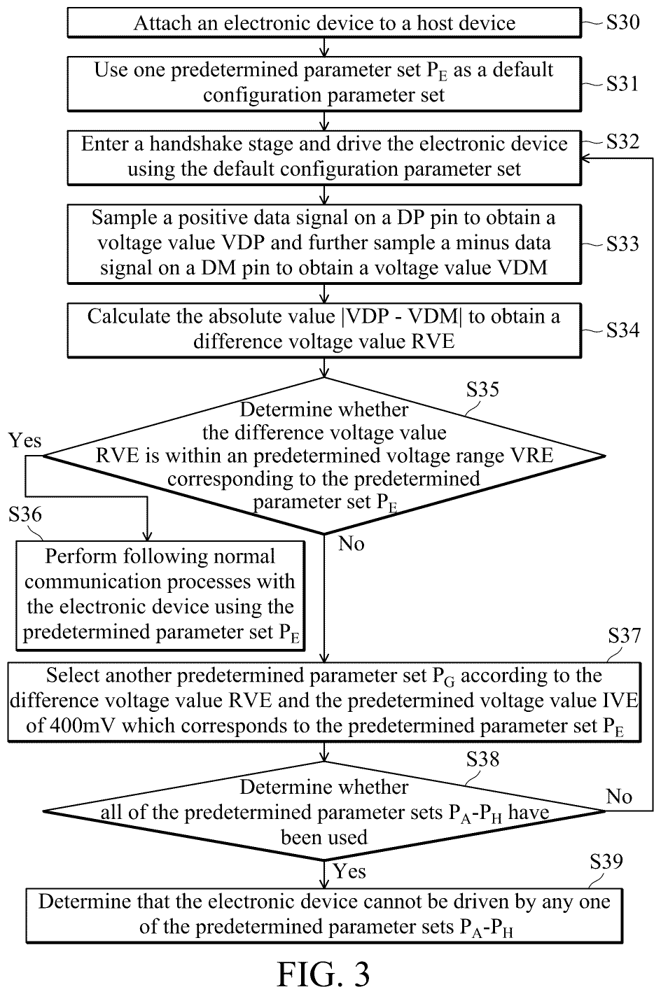

FIG. 3 shows an exemplary embodiment of a driving method. Referring to FIG. 1 and FIG. 3, when the electronic device 11 is attached to the host device 10 (Step S30), the controller 100 uses one of the predetermined parameter sets PA-PH as a default configuration parameter set (Step S31). For example, the controller 100 uses the predetermined parameter set PE as the default configuration parameter set. Then the host device 10 enters a handshake stage and drives the electronic device 11 using the default configuration parameter set PE (Step S32). In the handshake stage, after the terminal resistor R110 is connected to the DP pin P112, the ADC 101 samples a positive data signal DP on the DP pin P102 to obtain a voltage value VDP and further samples a minus data signal DM on the DM pin P103 to obtain a voltage value VDM (Step S33). The ADC 101 transmits the voltage values VDP and VDM to the controller 100.

The controller 100 calculates the absolute value |VDP−VDM | of the difference between the voltage values VDP and VDM to obtain a difference voltage value RVE (Step S34). Then, the controller 100 determines whether the difference voltage value RVE (|VDP−VDM|) is within the predetermined voltage range VRE corresponding to the predetermined parameter set P_{E} to generate a determination result (Step S35). When the determination result indicates that the difference voltage value RVE (|VDP−VDM|) is within the predetermined voltage range VRE (Step S35-Yes), the controller 100 performs the following normal communication processes with the electronic device 11 using the predetermined parameter set P_{E} (Step S36).

When the determination result indicates that the difference voltage value |VDP−VDM| is not within the predetermined voltage range VRE (Step S35-No), the controller 100 selects one of the other predetermined parameter sets P_{A}-P_{D} and P_{F}-P_{H} according to the difference voltage value RVE (|VDP−VDM|) and the predetermined voltage value IVE of 400 mV which corresponds to the predetermined parameter set PE as the configuration parameter set (Step S37), that is, the configuration parameter set is changed to another predetermined parameter set from the predetermined parameter set PE. Specifically, the controller 100 calculates the voltage shifting value between the predetermined voltage value IVE and the difference voltage value RVE (|VDP−VDM|) and calculates the number of voltage intervals between the difference voltage value RVE (|VDP−VDM|) and the predetermined voltage value IVE through dividing the voltage shifting value by the voltage interval of 20 mV, wherein the quotient obtained from the division operation serves as the number of intervals for searching the nest predetermined parameter set, and the sign (+ or −) of the quotient indicates a searching direction in the predetermined sequence of the predetermined voltage values IV_{A}-IV_{E}.

FIG. 2B is a schematic diagram showing an exemplary predetermined parameter sets and a difference voltage values RVE according to an exemplary embodiment. For example, the difference voltage value RVE (|VDP−VDM|) is equal to 360 mV. The controller 100 determines that the difference voltage value RVE (|VDP−VDM|) is not within the predetermined voltage range VRE (381 mV-419 mV). Then, the controller 100 calculates the voltage shifting value between the predetermined voltage value IVE and the difference voltage value RVE (|VDP−VDM|),and the calculated voltage shifting value is 40 mV (400 mV-360 mV). The controller 100 calculates the number of voltage intervals between the difference voltage value RVE (|VDP−VDM|) and the predetermined voltage value IVE through dividing the voltage shifting value of 40 mV by the voltage interval of 20 mV, and the obtained quotient obtained from the division operation is 2. Thus, the number of voltage intervals for searching the next predetermined parameter set is 2, and the sign (+) of the quotient indicates the searching direction toward the maximum in the predetermined sequence. Referring to FIG. 2B, the controller 100 selects the predetermined parameter set P_{G} which is away from the predetermined parameter set P_{E} by two voltage intervals as the configuration parameter set, that is, the configuration parameter set is changed to the predetermined parameter set P_{G} from the predetermined parameter set P_{E}.

In an embodiment, when the predetermined parameter set P_{G} has been selected after the electronic device 11 is attached to the host device 10, the controller 100 selects the predetermined parameter set closest to the predetermined parameter set P_{G}.

After Step S37, the controller 100 determines whether all of the predetermined parameter sets P_{A}-P_{H} have been used (Step S38). When the controller 100 determines that all of the predetermined parameter sets P_{A}-P_{H} have been used (Step S38-Yes), the controller 100 determines that the electronic device 11 cannot be driven by any one of the predetermined parameter sets P_{A}-P_{H} (Step S39). When the controller 100 determines that all of the predetermined parameter sets P_{A}-P_{H} have not been used (Step S38-No), the method proceeds to Step S32, and the host device 10 re-enters handshake stage and drives the electronic device 11 using the predetermined parameter set P_{G} to drive the electronic device 11.

According to the above embodiments, the host device 10 can adaptability use different predetermined parameter sets for driving different electronic devices without being affected by the materials or quality of transmission lines.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A host device, coupled to an electronic device, comprising:
an input/output (I/O) port comprising a first I/O pin and a second I/O pin, wherein the first I/O pin and the second I/O pin are coupled to the electronic device:
a controller coupled to the first I/O pin and the second I/O pin and configured to drive the electronic device using a configuration parameter set: and
an analog-to-digital converter coupled to the first I/O pin and the second I/O pin and configured to sample a first data signal on the first I/O pin to obtain a first voltage value and further to sample a second data signal on the second I/O pin to obtain a second voltage value,
wherein the controller receives the first voltage value and the second voltage value and changes the configuration parameter set according to the first voltage value and the second voltage value.

2. The host device as claimed in claim 1, wherein the electronic device is a USB OTG (On-The-Go) device.

3. The host device as claimed in claim 1, the controller provides a plurality of predetermined parameter sets which correspond to a plurality of predetermined voltage ranges respectively, and
wherein the controller changes the configuration parameter set according to a plurality of predetermined voltage ranges, the first voltage value and the second voltage value.

4. The host device as claimed in claim 1, wherein:
the controller provides a plurality of predetermined parameter sets which correspond to a plurality of predetermined voltage ranges respectively,
in response to that the controller uses one of the plurality of predetermined parameter sets as the configuration parameter set to drive the electronic device, the controller obtains a difference voltage value according to the first voltage value and the second voltage value and determines whether the difference voltage value is within a first predetermined voltage range in the plurality of predetermined voltage ranges which corresponds to the one of the plurality of predetermined parameter sets to generate a determination result, and
in response to the determination result indicating that the difference voltage value is not within the first predetermined voltage range, the controller uses one of the others of the plurality of predetermined parameter sets as the configuration parameter set for driving the electronic device.

5. The host device as claimed in claim 4, wherein in response to the determination result indicating that the difference voltage value is within the first predetermined voltage range, the controller uses the one of the plurality of predetermined parameter sets as the configuration parameter set for driving the electronic device.

6. The host device as claimed in claim 4, wherein:
the controller defines a plurality of predetermined voltage values corresponding to the plurality of predetermined voltage ranges respectively,
the controller defines a voltage interval to define the plurality of predetermined voltage values in a predetermined sequence, and
in response to the determination result indicating that the difference voltage value is not within the first predetermined voltage range, according to the difference voltage value, the predetermined voltage value corresponding to the first predetermined voltage range, and the voltage interval, the controller uses one of the others of the plurality of predetermined parameter sets as the configuration parameter set for driving the electronic device.

7. The host device as claimed in claim 6, wherein the controller defines the plurality of predetermined voltage values from the minimum to the maximum in the predetermined sequence, and a voltage interval is defined between any two adjacent predetermined voltage value.

8. The host device as claimed in claim 1, wherein in response to that the controller operates in a handshake stage to communicate with the electronic device, the controller samples the first data signal on the first I/O pin to obtain the first voltage value and further to samples the second data signal on the second I/O pin to obtain the second voltage value.

9. The host device as claimed in claim 8, wherein:
the first I/O pin and the second I/O pin are coupled to an I/O port of electronic device,
in response to that the controller operates in the handshake stage and a terminal resistor is connected to the I/O port of the electronic device, the sample the first data signal on the first I/O pin to obtain the first voltage value and further to sample the second data signal on the second I/O pin to obtain the second voltage value.

10. The host device as claimed in claim 8, wherein the handshake stage is a high-speed handshake process.

11. The host device as claimed in claim 1, wherein the first data signal and the second data signal are a differential pair of signals.

12. A driving method for an electronic device, comprising
inserting an electronic device to a host device, wherein an input/output (I/O) port of the host device comprises a first I/O pin and a second I/O pin which are coupled to the electronic device;
driving the electronic device using a configuration parameter set;
sampling a first data signal on the first I/O pin to obtain a first voltage value and a second data signal on the second I/O pin to obtain a second voltage value; and
changing the configuration parameter set according to the first voltage value and the second voltage value.

13. The driving method as claimed in claim 12, wherein the electronic device is a USB OTG (On-The-Go) device.

14. The driving method as claimed in claim 12, wherein:
a plurality of predetermined parameter sets which correspond to a plurality of predetermined voltage ranges respectively are provided,
driving the electronic device using a configuration parameter set comprises:
driving the electronic device using one of the plurality of predetermined parameter sets as the configuration parameter set:
changing the configuration parameter set according to the voltage value and the second voltage value comprises:
obtaining a difference voltage value according to the first voltage value and the second voltage value;
determining whether the difference voltage value is within a first predetermined voltage range in the plurality of predetermined voltage ranges which corresponds to the one of the plurality of predetermined parameter sets, and
in response to that the difference voltage value is not within the first predetermined voltage range, using one of the others of the plurality of predetermined parameter sets as the configuration parameter set for driving the electronic device.

15. The driving method as claimed in claim 14, wherein changing the configuration parameter set according to the voltage value and the second voltage value further comprises:
in response to the difference voltage value is within the first predetermined voltage range, uses the one of the plurality of predetermined parameter sets as the configuration parameter set for driving the electronic device.

16. The driving method as claimed in claim 14, wherein:
a plurality of predetermined voltage values corresponding to the plurality of predetermined voltage ranges respectively are defined,
a voltage interval is defined to define the plurality of predetermined voltage values in a predetermined sequence, and
changing the configuration parameter set according to the voltage value and the second voltage value further comprises:
in response to that the difference voltage value is not within the first predetermined voltage range, according to the difference voltage value, the predetermined voltage value corresponding to the first predetermined voltage range, and the voltage interval, using one of the others of the plurality of predetermined parameter sets as the configuration parameter set for driving the electronic device.

17. The driving method as claimed in claim 16, wherein the plurality of predetermined voltage values are defined from the minimum to the maximum in the predetermined sequence, and a voltage interval is defined between any two adjacent predetermined voltage value.

18. The driving method as claimed in claim 12, further:
performing a handshake stage to communicate with the electronic device,
wherein in the handshake stage, the first data signal on the first I/O pin is sampled, and the second data signal on the second I/O pin is sampled.

19. The driving method as claimed in claim 18, wherein:
the first I/O pin and the second I/O pin are coupled to an I/O port of electronic device,
in the handshake stage, a terminal resistor is connected to the I/O port of the electronic device, and
in the handshake stage, the first data signal on the first I/O pin is sampled and the second data signal on the second I/O pin is sampled.

20. The driving method as claimed in claim 18, wherein the handshake stage is a high-speed handshake process.

21. The driving method as claimed in claim 12, wherein the first data signal and the second data signal are a differential pair of signals.
